(19) United States
(12) Patent Application Publication
(10) Pub. No.: US 2007/0141786 A1
(43) Pub. Date: Jun. 21, 2007

(54) Method of manufacturing non-volatile memory element

(75) Inventors: Tsuyoshi Kawagoe, Tokyo (JP); Isamu Asano, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 11/637,069

(22) Filed: Dec. 12, 2006

(30) Foreign Application Priority Data
Dec. 15, 2005 (JP) 2005-362024

(51) Int. Cl. H01L 21/336

(52) U.S. Cl. 438/266

(57) ABSTRACT

A method of manufacturing a non-volatile memory element in the present invention comprises a first step for forming an adhesion layer on an interlayer insulating film so that an electrical connection is established with a lower electrode, a second step for forming a recording layer containing a phase change material on the adhesion layer, a third step for forming an upper electrode that is electrically connected to the recording layer, and a fourth step for diffusing in the recording layer some of the adhesion layer positioned between at least the lower electrode and the recording layer.

### TECHNICAL FIELD

The present invention relates to a method of manufacturing an electrically rewritable non-volatile memory element, and particularly relates to a method of manufacturing a non-volatile memory element having a recording layer that includes phase change material.

### BACKGROUND OF THE INVENTION

Personal computers and servers and the like use a hierarchy of memory devices. There is lower-tier memory, which is inexpensive and provides high storage capacity, while memory higher up the hierarchy provides high-speed operation. The bottom tier generally consists of magnetic storage such as hard disks and magnetic tape. In addition to being non-volatile, magnetic storage is an inexpensive way of storing much larger quantities of information than solid-state devices such as semiconductor memory. However, semiconductor memory is much faster and can access stored data randomly, in contrast to the sequential access operation of magnetic storage devices. For these reasons, magnetic storage is generally used to store programs and archival information and the like, and, when required, this information is transferred to main system memory devices higher up in the hierarchy.

Main memory generally uses dynamic random access memory (DRAM) devices, which operate at much higher speeds than magnetic storage and, on a per-bit basis, are cheaper than faster semiconductor memory devices such as static random access memory (SRAM) devices.

Occupying the very top tier of the memory hierarchy is the internal cache memory of the system microprocessor unit (MPU). The internal cache is extremely high-speed memory connected to the MPU core via internal bus lines. The cache memory has a very small capacity. In some cases, secondary and even tertiary cache memory devices are used between the internal cache and main memory.

DRAM is used for main memory because it offers a good balance between speed and bit cost. Moreover, there are now some semiconductor memory devices that have a large capacity. In recent years, memory chips have been developed with capacities that exceed one gigabyte. DRAM is volatile memory that loses stored data if its power supply is turned off. That makes DRAM unsuitable for the storage of programs and archival information. Also, even when the power supply is turned on, the device has to periodically perform refresh operations in order to retain stored data, so there are limits as to how much device electrical power consumption can be reduced, while yet a further problem is the complexity of the controls run under the controller.

Semiconductor flash memory is high capacity and non-volatile, but requires high current for writing and erasing data, and write and erase times are slow. These drawbacks make flash memory an unsuitable candidate for replacing DRAM in main memory applications. There are other non-volatile memory devices, such as magnetoresistive random access memory (MRAM) and ferroelectric random access memory (FRAM), but they cannot easily achieve the kind of storage capacities that are possible with DRAM.

Another type of semiconductor memory that is being looked to as a possible substitute for DRAM is phase change random access memory (PRAM), which uses phase change material to store data. In a PRAM device, the storage of data is based on the phase state of phase change material contained in the recording layer. Specifically, there is a big difference between the electrical resistivity of the material in the crystalline state and the electrical resistivity in the amorphous state, and that difference can be utilized to store data.

This phase change is effected by the phase change material being heated when a write current is applied. Data is read by applying a read current to the material and measuring the resistance. The read current is set at a level that is low enough not to cause a phase change. Thus, the phase does not change unless it is heated to a high temperature, so data is retained even when the power supply is switched off.

Chalcogenide materials such as Ge₂Sb₂Te₅ and the like are preferably used as the phase change material that constitutes the recording layer. The recording layer is substantially formed on an insulating film of silicon oxide or the like, but due to the relatively poor adhesion between the chalcogenide material and silicon oxide films or other insulating films, an adhesion layer of titanium (Ti) is often provided between the silicon oxide film and the recording layer (see Japanese Patent Application Laid Open. No. 2003-174144). The recording layer can accordingly be prevented from detaching during the manufacturing process.

### SUMMARY OF THE INVENTION

However, adhesion layers made of titanium or the like have an electrical resistance value that is much lower than that of typical phase change materials. Accordingly, even if phase transition is attempted using current supplied from a transistor, a region in which joule heat is generated will develop that will not be confined to the point of contact with the lower electrode, but will expand in the planar direction. Therefore, problems have arisen insofar as the heat generation efficiency decreases. As a result, there is a concern that it may be impossible to transition from the initial post-manufactured state (crystalline state) to the reset state (amorphous state), depending on the performance provided by the current from the transistor, and memory function may not occur.

It is therefore an object of the present invention to provide a method of manufacturing a phase change non-volatile memory element with increased heat generation efficiency while still ensuring adequate adhesion between the recording layer and the insulating film during the manufacturing process.

The above an other object of the present invention can be accomplished by a method of manufacturing a non-volatile memory element comprising a first step for forming an adhesion layer on an interlayer insulating film so that an electrical connection is established with a lower electrode, a second step for forming a recording layer containing a phase change material on the adhesion layer, a third step for forming an upper electrode that is electrically connected to the recording layer, and a fourth step for diffusing in the recording layer some of the adhesion layer positioned between at least the lower electrode and the recording layer.

In the present invention, the second step preferably includes a step wherein the phase change material is formed into a film in an inert gas atmosphere with which an additive has been mixed, the additive preferably being nitrogen. The nitrogen or other additive can thereby be added to the recording layer. When nitrogen or another additive is added to the recording layer, the crystal grains of the recording layer become smaller than in conventional recording layers without additives. Since the crystal grain boundary also increases, the adhesion layer is more readily diffused into the recording layer. It is therefore believe that when a heat treatment or the like is performed, the elements constituting the adhesion layer will gradually diffuse into the recording layer along the grain boundary of the recording layer, and ultimately the effect of the adhesion layer will dissipate. Additionally, since the resistivity of a recording layer with added nitrogen is larger than the resistivity of a recording layer without additives, an effect is also obtained wherein the rewriting current is reduced.

The amount of nitrogen added is preferably 1 to 10% in terms of the ratio of flow relative to that of the inert gas. This is because if the amount of added nitrogen is below this range, the recording layer crystal grain boundary necessary for diffusion of the adhesion layer will not form, and if the amount exceeds the above range, the crystals of the recording layer will be too fine, and an adequate resistance ratio between the crystalline state and the amorphous state cannot be obtained.

In the present invention, the interlayer insulating film preferably includes silicon oxide (SiO₂), and the adhesion layer preferably contains titanium (Ti). This is because when titanium is provided between the recording layer and the interlayer insulating film of silicon oxide or the like, the adhesion of the recording layer and the interlayer insulating film can thereby be adequately increased.

The film thickness of the adhesion layer is preferably established to be as low as possible while still ensuring the adhesiveness of the recording layer, and is ideally 1 to 4 nm. This is because if the film thickness of the adhesion layer is less than 1 nm, the adhesion may not be adequately retained, and if the thickness exceeds 4 nm, diffusion of the adhesion layer may be difficult.

In the present invention, the phase change material preferably contains a chalcogenide material. Ge₂Sb₂Te₅ (GST) is especially preferred as the chalcogenide material. When nitrogen is added to Ge₂Sb₂Te₅, the crystal grain size becomes smaller than in conventional Ge₂Sb₂Te₅. The crystal grain boundary also increases, allowing diffusion of the adhesion layer into the Ge₂Sb₂Te₅ to be more readily performed. It is believed that performing a heat treatment and supplying a rewriting current causes the adhesion layer to diffuse gradually into the recording layer along the boundary of the grains that constitute the recording layer, and the effect of the adhesion layer to ultimately disappear. Additionally, since the resistivity of Ge₂Sb₂Te₅ with added nitrogen is larger than the resistivity of Ge₂Sb₂Te₅ without any additive, an effect is also observed wherein the rewriting current is reduced.

In the present invention, the fourth step preferably includes a step for performing a heat treatment at a prescribed temperature. The prescribed temperature is preferably 350° C. or more. It is believed that when a heat treatment is performed, the elements constituting the adhesion layer gradually diffuse into the recording layer along the grain boundary of the recording layer, and the effect of the adhesion layer ultimately disappears. Therefore, the desired resistance ratio between the crystalline phase and the amorphous phase can be obtained. Additionally, since the resistivity of a recording layer with added nitrogen is larger than the resistivity of a recording layer without an additive, an effect is also observed wherein the rewriting current is reduced.

In the present invention, the fourth step may be an initialization step for repeating the rewriting of the recording layer. In such instances, the number of repeated rewritings is preferably 10⁵ or more. It is believed that when an initialization step is performed, the elements constituting the adhesion layer gradually diffuse into the recording layer along the grain boundary of the recording layer, and the effect of the adhesion layer ultimately disappears. Therefore, the desired resistance ratio between the crystalline phase and the amorphous phase can be obtained.

According to the present invention, there can be provided a method of manufacturing a phase change non-volatile memory element increased heat generation efficiency while ensuring adequate adhesion between the recording layer and the insulating film during the manufacturing process.

### BRIEF DESCRIPTION OF THE DRAWINGS

The above and other objects, features and advantages of this invention will become more apparent by reference to the following detailed description of the invention taken in conjunction with the accompanying drawings, wherein:

FIG. 1 is a schematic sectional view showing a method of manufacturing a non-volatile memory element (specifically forming a transistor layer 100) according to a first preferred embodiment of the present invention;

FIG. 2 is a schematic sectional view showing a method of manufacturing a non-volatile memory element (specifically forming a transistor layer 100) according to a first preferred embodiment of the present invention;

FIG. 3 is a schematic sectional view showing a method of manufacturing a non-volatile memory element (specifically forming contact holes 11a) according to a first preferred embodiment of the present invention;

FIG. 4 is a schematic sectional view showing a method of manufacturing a non-volatile memory element (specifically forming lower electrodes 12) according to a first preferred embodiment of the present invention;

FIG. 5 is a schematic sectional view showing a method of manufacturing a non-volatile memory element (specifically polishing down the lower electrodes 12) according to a first preferred embodiment of the present invention;

FIG. 6 is a schematic sectional view showing a method of manufacturing a non-volatile memory element (specifically forming an adhesion layer 14) according to a first preferred embodiment of the present invention;

FIG. 7 is a schematic sectional view showing a method of manufacturing a non-volatile memory element (specifically forming a recording layer 15) according to a first preferred embodiment of the present invention;

FIG. 8 is a schematic sectional view showing a method of manufacturing a non-volatile memory element (specifically forming an upper electrode 16) according to a first preferred embodiment of the present invention;

FIG. 9 is a schematic sectional view showing a method of manufacturing a non-volatile memory element (specifically forming a bit line Bj) according to a first preferred embodiment of the present invention;

FIG. 10 is a schematic sectional view showing a method of manufacturing a non-volatile memory element (specifically diffusing the adhesion layer 14) according to a first preferred embodiment of the present invention;

FIG. 11 is a circuit diagram of a non-volatile semiconductor memory device having an n×m matrix configuration;

FIG. 12 is a graph for describing a method for controlling the phase state of the recording layer 15;

FIG. 13 is a flowchart showing a method of manufacturing a non-volatile memory element according to a second preferred embodiment of the present invention;

FIG. 14 is a schematic sectional view showing a method of manufacturing a non-volatile memory element (specifically diffusing the adhesion layer 14) according to a first preferred embodiment of the present invention;

FIG. 15 is a graph showing resistance values of the recording layer 15 during the rewriting operation; and

FIG. 16 is a flowchart showing a method of manufacturing a non-volatile memory element according to a third preferred embodiment of the present invention.

### DESCRIPTION OF THE PREFERRED EMBODIMENTS

Preferred embodiments of the present invention will now be explained in detail below with reference to the accompanying drawings.

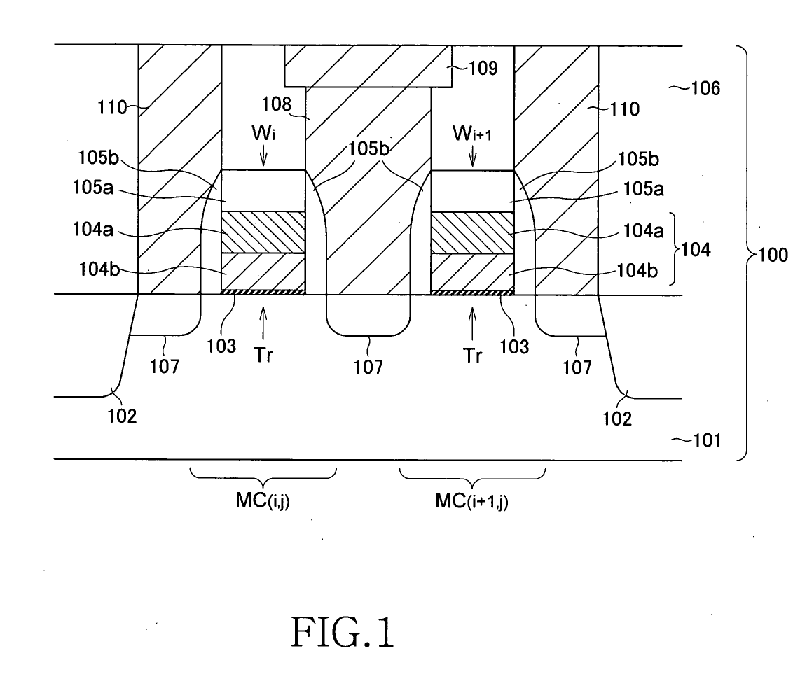

FIGS. 1 through 10 are schematic sectional views showing a method of manufacturing a non-volatile memory element according to a first preferred embodiment of the present invention.

In the method of manufacturing a non-volatile memory element according to the present embodiment, first, a transistor layer 100 is formed on a semiconductor substrate 101 (FIG. 1). The structure and method for forming the transistor layer 100 are not particularly limited, and the transistor layer 100 may be formed using a well-known method. The transistor layer 100 shown in the drawing has two transistors Tr. Gates 104 of the transistors Tr are each configured with a word line Wi, Wi+1. The gates 104 have a polycide structure composed of a polysilicon film 104a and tungsten silicide (WSi) 104b, and are formed on a gate insulating film 103. The upper part of the gates 104 has a gate cap 105a, having side walls 105b on the lateral surfaces thereof. Additionally, three diffusion regions 107 are formed in one activated region that is partitioned by element separation regions 102, whereby the two transistors Tr are formed in one active region. The two transistors Tr have a common source, and are connected to ground wiring 109 via a contact plug 108 provided to an interlayer insulating film 106. Further, the drain of each transistor Tr is connected via respective contact plugs 110 to a lower electrode of a non-volatile memory element described hereinafter.

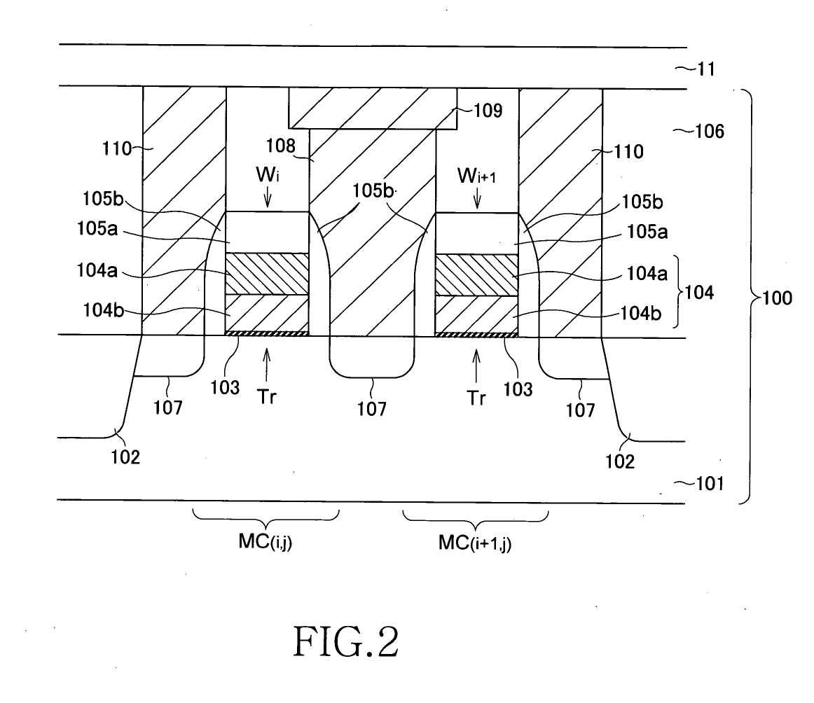

Next, an interlayer insulating film 11 is formed on the transistor layer 100 (FIG. 2). A silicon oxide film or the like may be used as the material of the interlayer insulating film 11. Ordinary CVD methods may be used to form the interlayer insulating film 11.

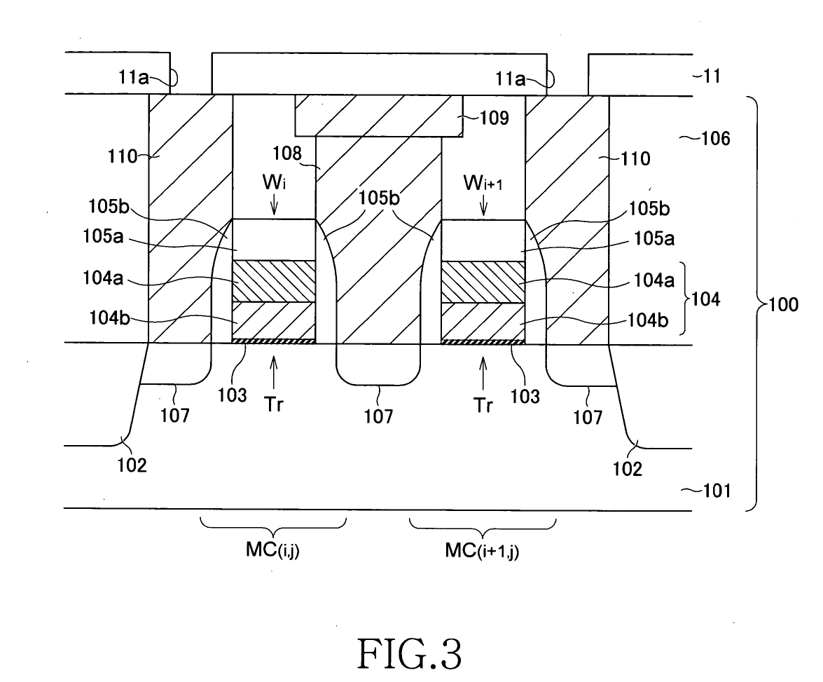

Next, two contact holes 11a are formed in the interlayer insulating film 11 (FIG. 3). The lower electrodes 12 are intended to be embedded in the contact holes 11a. The diameter thereof is set to be sufficiently smaller than the diameter of normal contact holes made for obtaining electrical conduction. The locations in which the contact holes 11a are formed are directly above the contact plugs 110 that are connected to the drains of the transistors Tr. General photolithography and dry etching may be used to form the contact holes 11a.

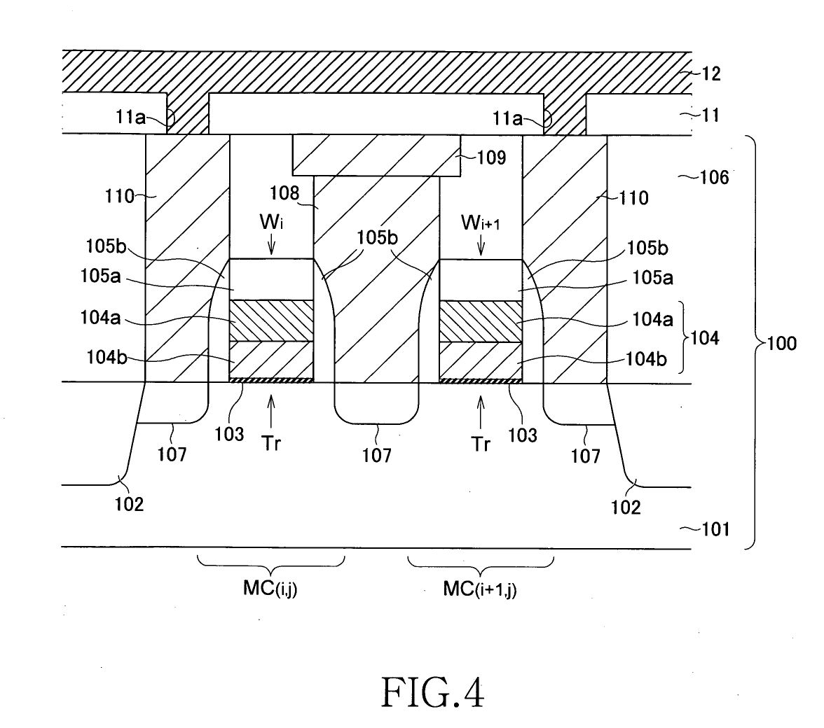

Next, the lower electrodes 12 are formed on the interlayer insulating film 11 so as to be completely buried within the contact holes 11a (FIG. 4). The lower electrodes 12 are used as heater plugs and become a part of the heat-generating body during data writing. Accordingly, materials with a comparatively high electrical resistance, such as metal silicides, metal nitrides, nitrides of metal silicides, and the like are preferably used as the material of the lower electrodes 12. It is possible to use W, TiN, TaN, WN, TiAlN, and other refractory metals or nitrides thereof; TiSiN, WSiN, and other nitrides of refractory metal silicides; TiCN; and other materials, although there are no limitations with regard thereto. As described above, the diameter of the lower electrodes 12 is preferably smaller than the diameter of normal contact plugs. The current path can thereby be concentrated at the lower electrodes 12, and the heat generation region can be focused on the vicinity of the distal end of the electrodes 12. A method for film formation with exceptional step coverage, such as formation by a CVD method, is preferred for the formation of the lower electrodes 12, which can thereby be completely buried within the contact holes 11a.

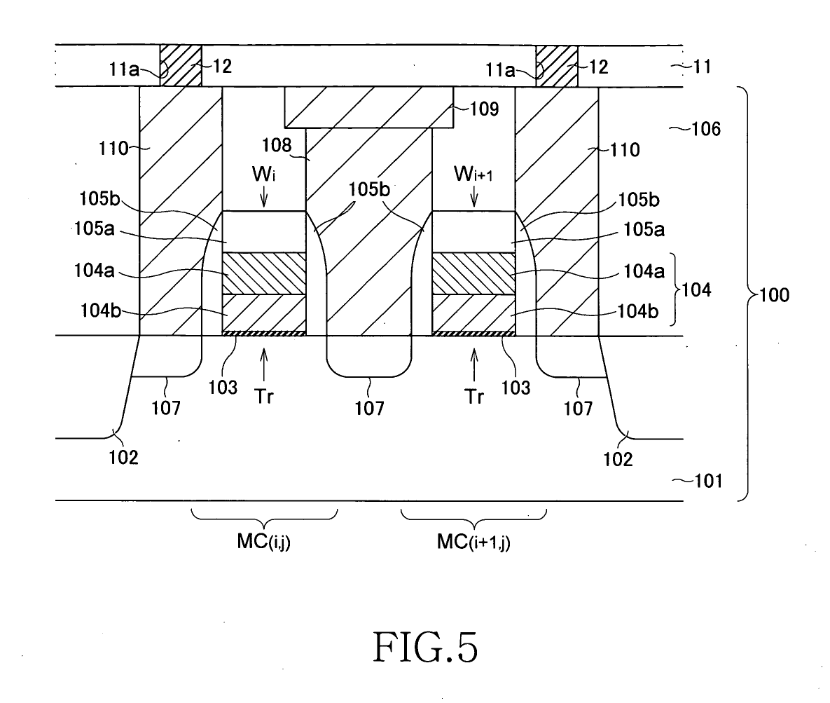

The lower electrodes 12 are then polished down so that the upper surface of the interlayer insulating film 11 is exposed (FIG. 5). A CMP method is preferably used for polishing. As a result, the lower electrodes 12 will be in an embedded state within the contact holes 11a.

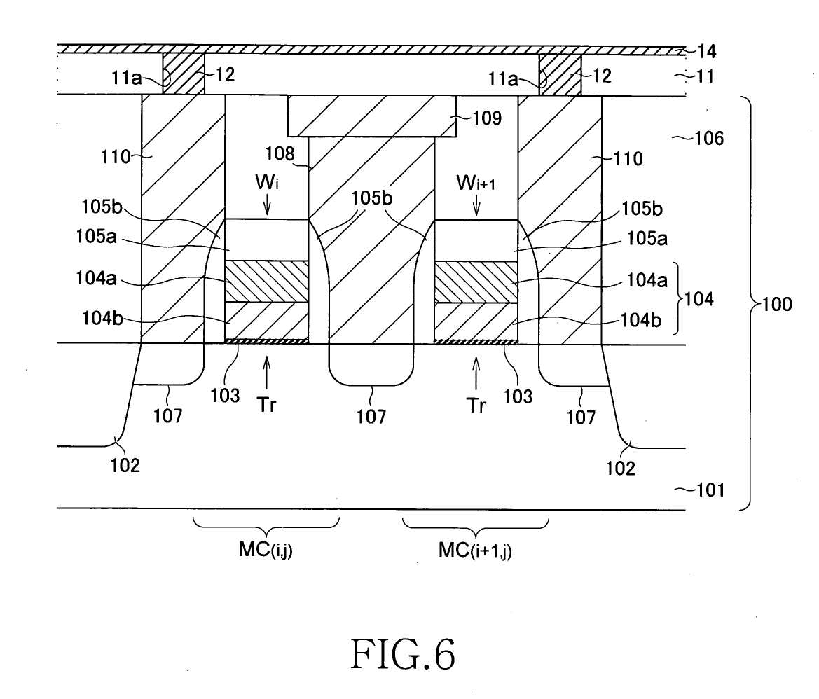

Next, an adhesion layer 14 is formed on the entire surface of the interlayer insulating film 11, including the end surfaces of the lower electrodes 12 (FIG. 6). Metals such as Ti, or metal compounds such as TiN are preferably used as the material for the adhesion layer 14. The film thickness of the adhesion layer 14 is preferably established to be as low as possible while still ensuring the adhesion of the recording layer, and is ideally 1 to 4 nm. This is because if the film thickness of the adhesion layer 14 is less than 1 nm, adequate adhesion may not be able to be retained, and if the thickness exceeds 4 nm, diffusion of the adhesion layer 14 as described hereinafter may be difficult. Sputtering methods, heat CVD methods, plasma CVD methods, ALD (Atomic Layer Deposition) methods, or the like may be used to form the adhesion layer 14. The entire surface of the interlayer insulating film 11, including the end surfaces of the lower electrodes 12, will thereby be covered by the adhesion layer 14.

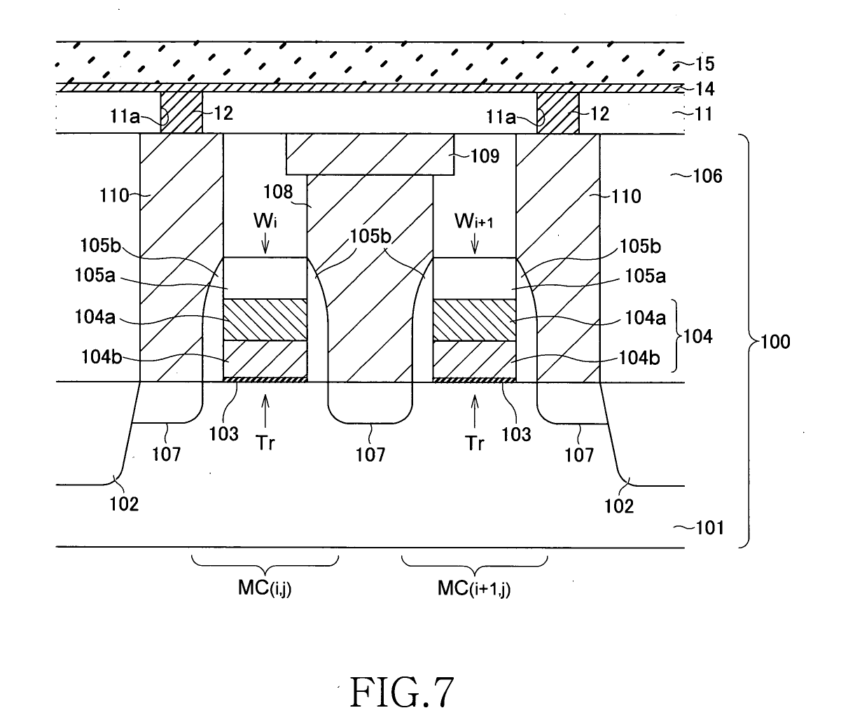

Next, a recording layer 15 is formed on the adhesion layer 14 (FIG. 7). A phase change material is used in the recording layer 15. The phase change material is not particularly limited insofar as the material assumes two or more phase states and has an electrical resistance that changes according to the phase state. A so-called chalcogenide materials is preferably selected. Chalcogenide material is defined as an alloy that contains at least one or more elements selected from the group consisting of germanium (Ge), antimony (Sb), tellurium (Te), indium (In), selenium (Se), and the like. Examples include GaSb, InSb, InSe, Sb₂Te₃, GeTe, and other binary-based elements; Ge₂Sb₂Te₅, InSbTe, GaSeTe, SnSb₂Te₄, InSbGe, and other ternary-based elements; and AgInSbTe, (GeSn)SbTe, GeSb(SeTe), Te₈₁Ge₁₅Sb₂S₂, and other quaternary-based elements. Ge₂Sb₂Te₅ (GST) in particular is preferably selected for the present embodiment.

The film thickness of the recording layer 15 is not particularly limited, but may be set, e.g., at 10 to 200 nm in the present embodiment. A sputtering may be used to form a film of the recording layer 15. During this process, nitrogen is added to the recording layer 15 by charging nitrogen gas (N₂) into the chamber along with argon gas (Ar) or another inert gas. The nitrogen is added in order to reduce the crystal grain diameter of the phase change material. This process is described in detail hereinafter, but if nitrogen is not added to the phase change material, then the crystal grain diameter of the phase change material increases and the grain boundary decreases; therefore, diffusion of the adhesion layer 14 becomes difficult. However, when nitrogen is added to a phase change material, and particularly Ge₂Sb₂Te₅ (GST), several nitrogen atoms do not properly enter the interstitial space of the chalcogenide material and are deposited as nitrides within the crystal grains or within the crystal grain boundary. In other words, the crystal grain diameter of the phase change material decreases, and the grain boundary increases; therefore, diffusion of the adhesion layer 14 into the recording layer 15 is more readily accomplished.

The amount of nitrogen added is approximately several percentage points in terms of the ratio of flow relative to the argon gas (Ar). More specifically, an amount of approximately 1 to 10% is preferable. This is because if the amount of supplied nitrogen is less than 1%, the recording layer 15 crystal grain boundary necessary for diffusion of the adhesion layer 14 will not be obtained, and if the amount is more than 10%, the crystals of the recording layer 15 will be too fine, and an adequate resistance ratio between the crystalline state and the amorphous state will be impossible to obtain.

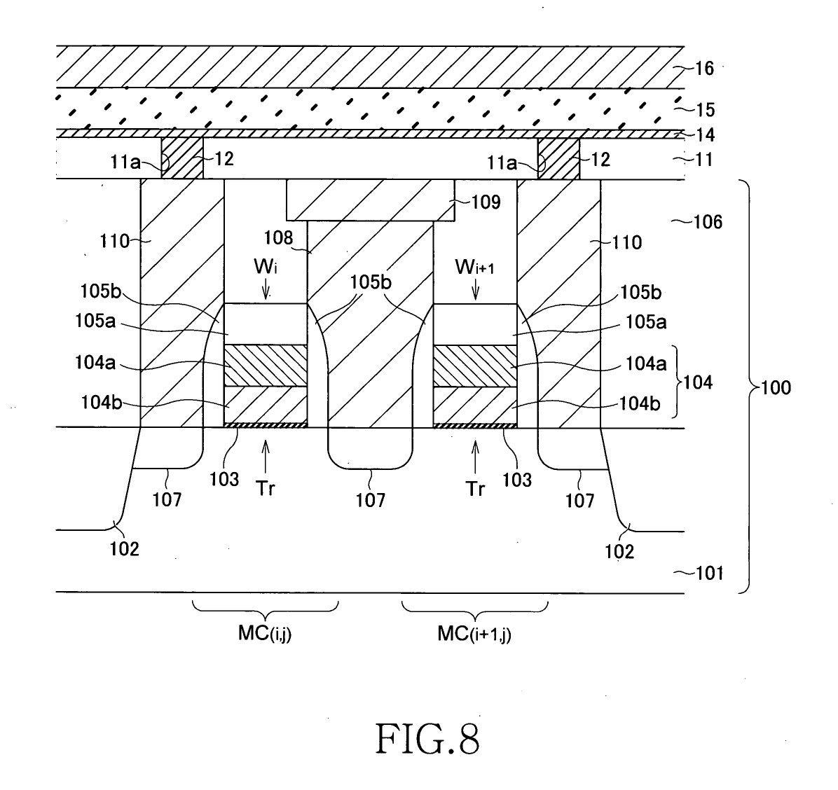

Next, an upper electrode 16 is formed on the recording layer 15 (FIG. 8). The upper electrode 16 constitutes a pair with the lower electrode 12. The material used for the upper electrode 16 preferably has relatively low thermal conductivity, so that the heat produced by the passage of electric current will tend not to escape. Specifically, TiAlN, TiSiN, TiCN, and other such materials are preferably used as the lower electrode 12.

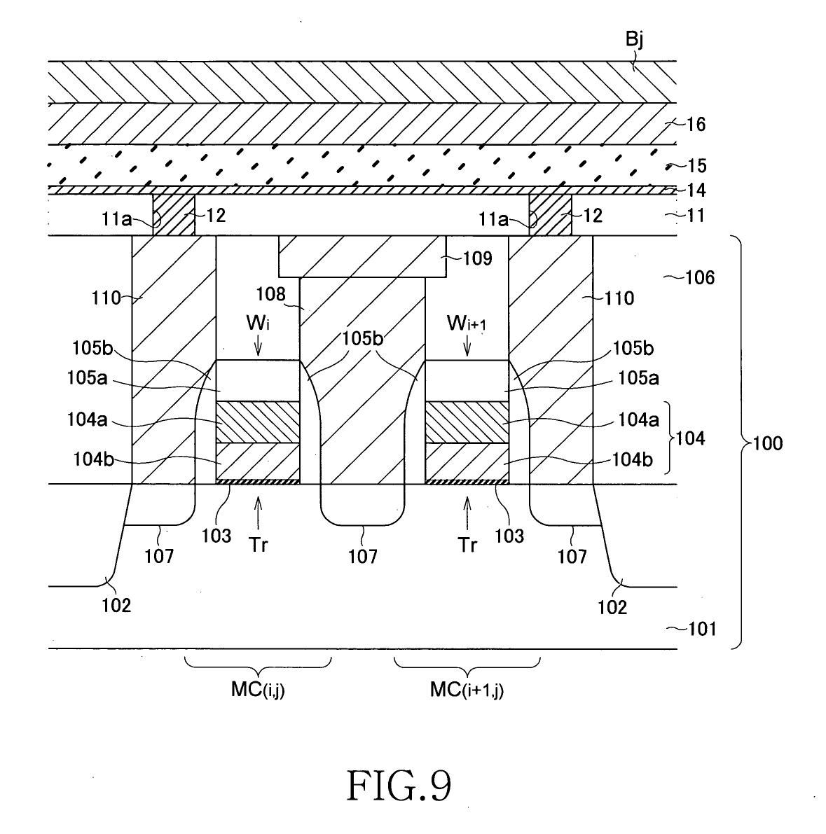

Next, a bit line Bj is formed on the upper electrode 16 (FIG. 9). The bit line Bj, the upper electrode 16, the recording layer 15, and the adhesion layer 14 are then patterned into a prescribed form. The bit line Bj is connected in common to two upper electrodes 16 of non-volatile memory elements 10. Accordingly, the two upper electrodes 16 of non-volatile memory elements 10 do not need to be separated, and can be fashioned into a continuous configuration, as shown in the drawing.

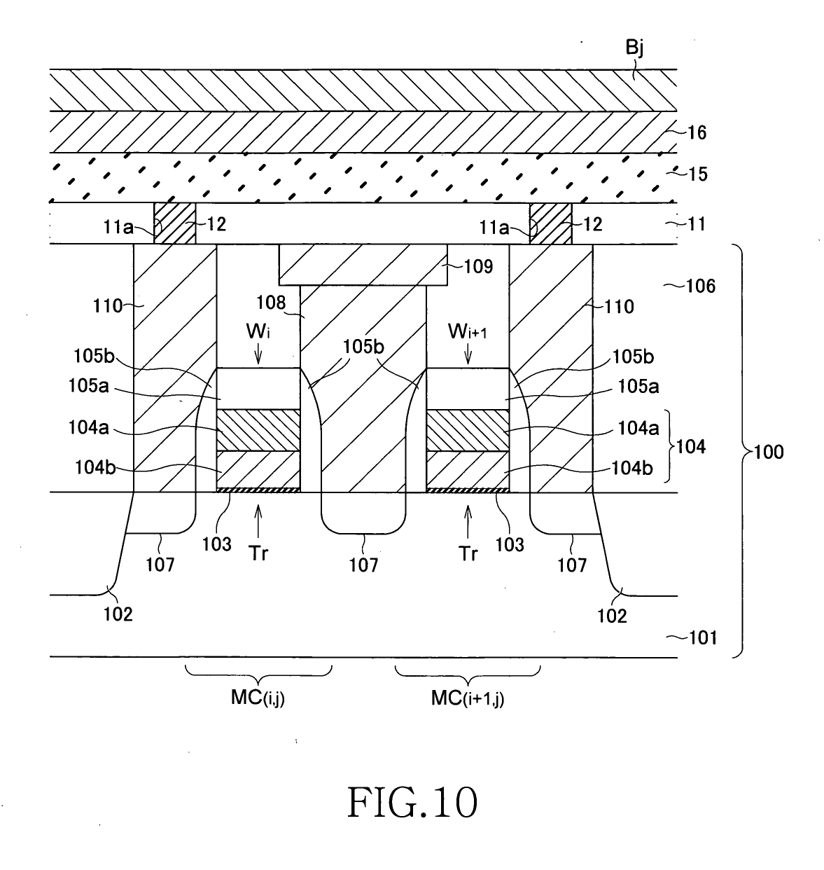

Several steps involving heating to approximately 400° C. for forming the interlayer insulating film are then performed in order to complete the final product. Therefore, the Ti in the adhesion layer 14 gradually diffuses into the recording layer 15 over the course of such heat treatments, and when the final product is completed as a non-volatile semiconductor memory device that accommodates the non-volatile memory element 10, the adhesion layer 14 substantially disappears (FIG. 10). When current is supplied via the transistors Tr, a region of joule heat generation is thereby concentrated on the areas in which contact is made with the lower electrodes 12, and high heat generation efficiency can therefore be obtained. Conversion from the initial set state (crystalline state) after manufacturing to the reset state (amorphous state) can thereby be easily executed. Furthermore, problems also arise in regard to the adhesiveness of the recording layer 15 due to diffusion of the Ti of the adhesion layer 14. However, whereas the compressive stress of a recording layer 15 without additives is 0 Mpa, a recording layer 15 with added nitrogen will change to have a compressive stress of 20 to 30 Mpa. As the adhesion improves, the adhesion layer 14 is regarded to have finished serving its purpose.

A non-volatile memory element 10 having this configuration is configured with two memory cells MC(i, j), MC(i+1, j) sharing a corresponding bit line Bj. An electrically rewritable non-volatile semiconductor memory device may be configured by positioning the memory cells MC together with the transistors Tr in the form of a matrix.

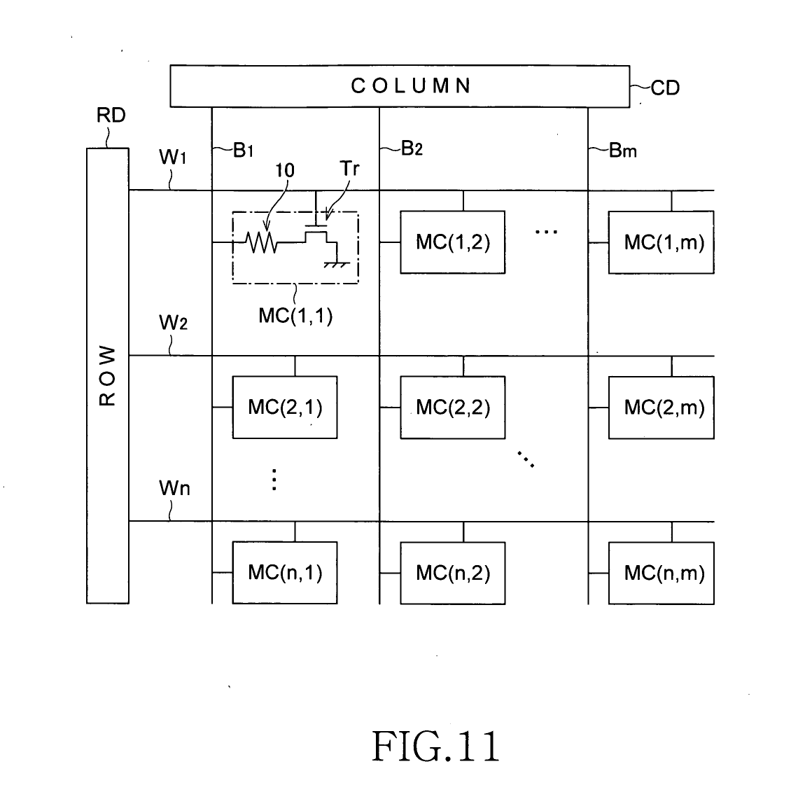

FIG. 11 is a circuit diagram of a non-volatile semiconductor memory device having an n×m matrix configuration.

The non-volatile semiconductor memory device shown in FIG. 11 is provided with n word lines W1 through Wn, m bit lines B1 through Bm, and memory cells MC(1,1) through MC(n,m) positioned at the intersection points of each word line and bit line. Word lines W1 through Wn are connected to a row decoder RD, and the bit lines B1 through Bm are connected to a column decoder CD. Each memory cell MC is configured from the transistor Tr and non-volatile memory element 10 that are serially connected between a ground and the corresponding bit line. Control terminals of the transistors Tr are connected to the corresponding word lines.

A non-volatile semiconductor memory device having such a configuration activates any one of the word lines W1 through Wn via the row decoder RD. In this state, reading and writing of data can be performed by passing a current to at least one of the bit lines B1 through Bm. In other words, in a memory cell wherein the corresponding word line is activated, the corresponding bit line becomes connected to the ground via the non-volatile memory element 10 when the transistor Tr is turned on. Therefore, if a writing current is applied to a prescribed bit line selected by the column decoder CD in this state, the recording layer 15 included in the non-volatile memory element 10 can be made to change phase.

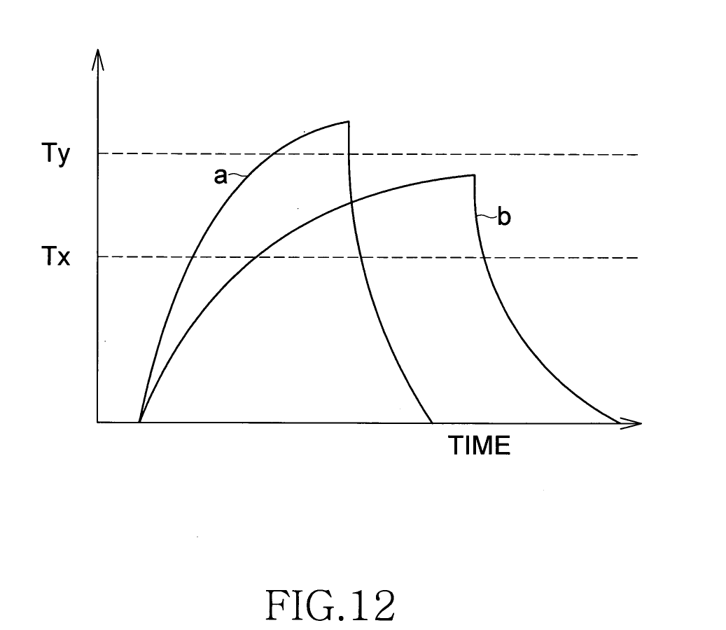

FIG. 12 is a graph for describing a method for controlling the phase state of the recording layer 15.

The phase change material that constitutes the recording layer 15 can have either an amorphous (non-crystalline) or crystalline phase state. The amorphous phase is a relatively high resistance state, and the crystalline phase is a relatively low resistance state. As shown by curve “a” of FIG. 12, in order to bring the phase change material into an amorphous state, short high voltage pulses are added and heating is briefly applied at a temperature at or above a melting point Ty, after which rapid cooling may be performed. Alternatively, as shown by curve “b” of FIG. 12, in order to bring a phase change material that contains a chalcogenide into a crystalline state, long low voltage pulses are added, and the temperature may be maintained at or above a crystallization temperature Tx and below the melting point Ty. Heating can be performed by passing an electric current. The temperature upon heating can be controlled by the amount of electricity; i.e., by the time during which the electric current is passed or the amount of current passed per unit time.

As also applies when reading data, any one of the word lines W1 through Wn is activated via the row decoder RD, and a reading current may be applied in this state to at least one of the bit lines B1 through Bm. Since the resistance of the recording layer 15 in a memory cell increases in the amorphous phase and decrease in the crystalline phase, the phase state of the recording layer 15 can be determined by detecting this resistance with a sensing amp not shown in the drawings.

The phase state of the recording layer 15 can be correlated with a stored logical value. For example, defining an amorphous phase state is defined as “0” and the crystalline phase state as “1” makes it possible for a single memory cell to retain 1-bit data. The crystallization ratio can also be controlled in multi-stage or linear fashion by adjusting the time for which the recording layer 15 is maintained at or above the crystallization temperature Tx and below the melting point Ty when a change occurs from the amorphous phase to the crystalline phase. Performing multi-stage control of the mixture ratio of amorphous states and crystalline states by this type of method makes it possible for 2-bit or higher order data to be stored in a single memory cell. Furthermore, Performing linear control of the mixture ratio of amorphous states and crystalline states makes it possible to store analog values.

As explained above, in a non-volatile memory element 10 of the present embodiment, the adhesion layer 14 on the boundary surface between the lower electrodes 12 and the recording layer 15 can be diffused away during the manufacturing step by the addition of nitrogen into the recording layer 15, which is composed of GST or another chalcogenide material. Since the heat generation efficiency can thereby be raised, a set state (crystalline state) can be readily converted to a reset state (amorphous state). Additionally, the recording layer 15 can be prevented from detaching during the processing and rinsing steps following the formation of the recording layer 15 since the adhesion layer 14 is provided between the interlayer insulating film 11 and the recording layer 15.

Furthermore, in the present embodiment, diffusion of the adhesion layer 14 is facilitated by the addition of nitrogen to the recording layer 15, but materials other than nitrogen may also be added to the recording layer 15 as long as the crystal grains of the phase change material can be reduced in size. Additionally, in the present embodiment, the addition of nitrogen or the like to the recording layer 15 is not mandatory. For example, the adhesion layer 14 may also be diffused by performing a heat treatment for extended periods of time.

Thus, in the present embodiment, decreases in productivity or other such problems do not occur since nitrogen can be admixed merely with the sputtering gas used in forming the recording layer 15 without adding any special steps.

In the first embodiment described above, the adhesion layer 14 is diffused into the recording layer 15. Therefore, nitrogen is added to the GST or other chalcogenide material that constitutes the recording layer 15, and diffusion of the Ti that constitutes the adhesion layer 14 is induced by subsequent heat treatments. However, an adequate resistance ratio between the crystalline phase and the amorphous phase can be obtained using a chalcogenide material with no added nitrogen. Such a method will be explained in detail below.

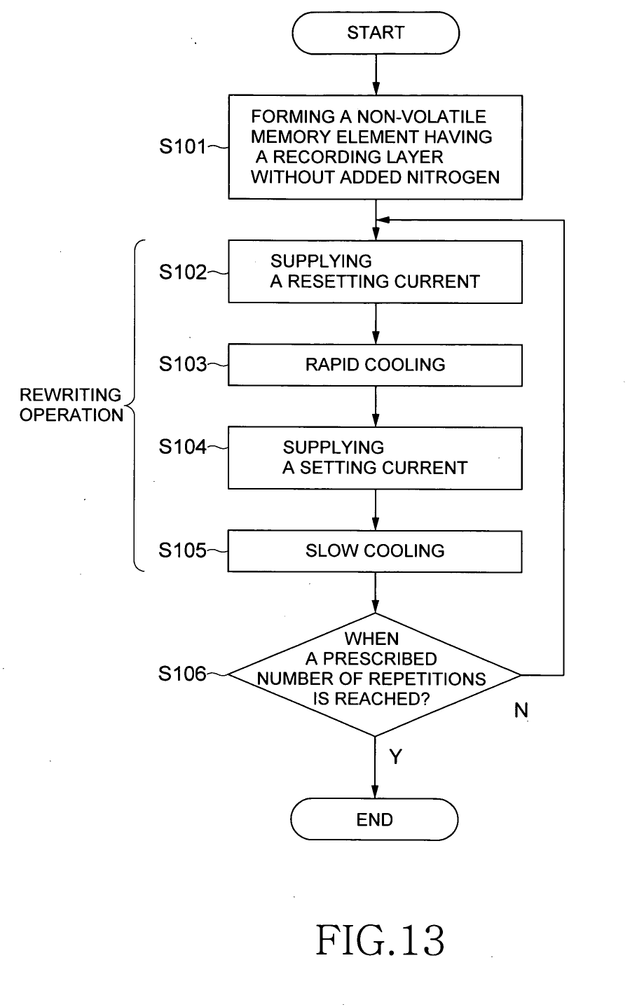

FIG. 13 is a flowchart showing a method of manufacturing a non-volatile memory element according to a second preferred embodiment of the present invention.

As shown in FIG. 13, in the manufacture of a non-volatile memory element according to the present embodiment, first, a non-volatile memory element having a recording layer 15 without added nitrogen is formed (S101). The non-volatile memory element can be manufactured according to the manufacturing steps shown in FIGS. 1 through 10. A recording layer 15 without added nitrogen can be formed by not passing nitrogen gas (N₂) into the chamber during the recording layer 15 formation step (FIG. 7). Thereafter, the non-volatile memory element is manufactured by carrying out the same steps as above.

Next, initialization steps (S102 through S106) are carried out in order to ensure the desired resistance ratio between the crystalline phase and the amorphous phase of the recording layer 15. In the initialization steps, first, a resetting current is supplied to change the recording layer 15 from a crystalline state to an amorphous state (S102). When a resetting current is fed through the transistors, the current path concentrates at the lower electrodes 12, and the recording layer 15 is therefore heated in the vicinity of the distal ends of the lower electrodes 12. The recording layer 15 will assume an amorphous phase if short high voltage pulses are thus added, the recording layer 15 is briefly heated at a temperature at or above a melting point Ty, and rapid cooling is then performed (S103). Such resetting actions require the heated recording layer to be rapidly cooled and the electric current to be passed for a time that is needed to heat the recording layer to a temperature at or above the melting point to be ensured. Therefore, the time required for the resetting operation is several tens of nanoseconds. The heat produced in this step causes the Ti and other low-resistance materials that compose the adhesion layer 14 to slightly diffuse into the recording layer 15, and the film thickness of the adhesion layer 14 decreases in proportion thereto. However, at the start of the initialization step, the region of joule heat generation will not concentrate at the areas where contact is made with the lower electrodes that serve as heaters, and heat will expand in the planar direction due to the presence of the adhesion layer 14, which has low electrical resistance. Thus, a transition to the amorphous phase may initially not occur even when a resetting current is applied.

Next, a setting current is supplied in order to crystallize the amorphous recording layer 15 (S104). When a setting current is supplied through the transistors, the current path is concentrated at the lower electrodes 12, and the recording layer 15 is therefore heated in the vicinity of the distal ends of the lower electrodes 12. The recording layer 15 will assume a crystalline phase if long low voltage pulses are thus added and the temperature is kept at or above a crystallization temperature Tx and below the melting point Ty (S105). Such setting operations require the heated recording layer to be slowly cooled and the electric current to be passed for a time needed to heat the recording layer to the crystallization temperature to be ensured. Therefore, the time required for the setting operation is several hundred nanoseconds. In this step as well, the resulting heat will cause the Ti and other low-resistance materials that constitute the adhesion layer 14 to slightly diffuse into the recording layer 15, and the film thickness of the adhesion layer 14 will decrease in proportion thereto.

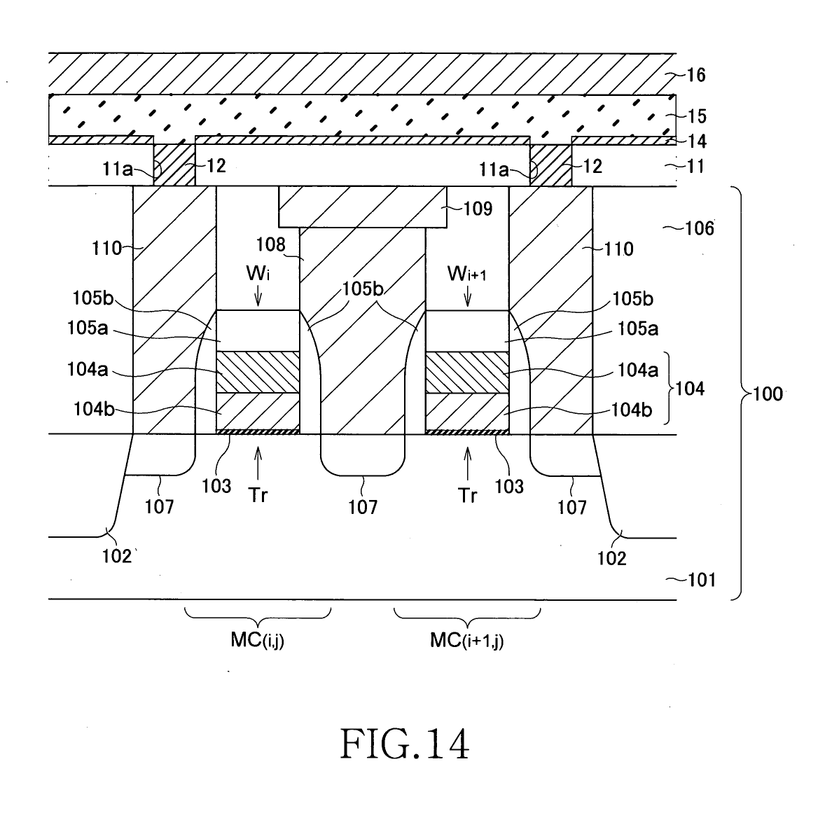

In the initialization step, the application of joule heat by the supply of setting and resetting currents in the above-described manner is repeated (S102 through S105, S106N). When a prescribed number of repetitions; e.g., approximately 10⁶ to 10⁷, is reached (S104Y), the initialization step is concluded. As a result of the initialization step, the Ti and other low-resistance materials that constitute the adhesion layer 14 will diffuse, and the adhesion layer 14 on the boundary surface between the lower electrodes 12 and the recording layer 15 will partially disappear as shown in FIG. 14. In other words, the performing of the initialization step allows the heat generation efficiency of the non-volatile memory element to be increased, and a set state (crystalline state) to be readily converted to a reset state (amorphous state).

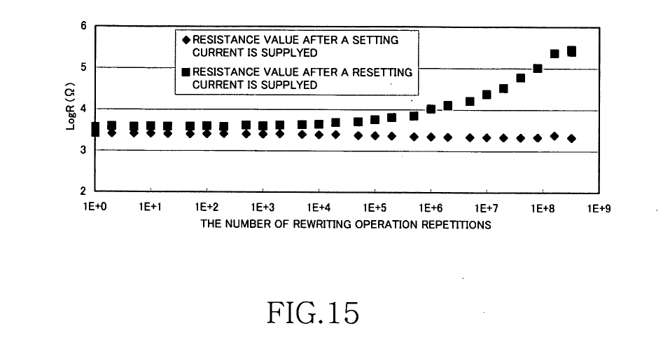

FIG. 15 is a graph showing resistance values of the recording layer 15 during the rewriting operation. In FIG. 15, the horizontal axis represents the number of rewriting operation repetitions, and the vertical axis represents the resistance value (Ω).

As shown in FIG. 15, until approximately 10⁵ rewriting cycles, the transition to the amorphous state is not attained even when a resetting current is applied, and the recording layer 15 remains in the crystalline state. Thus, the resistance value after a resetting current is supplied differs little from the resistance value after a setting current is supplied. However, once the rewriting operation of the recording layer 15 is repeated and passes approximately 10⁵ cycles, an increase in the resistance value can be observed due to the formation of the amorphous phase. Once 10⁶ repetitions have been made, the resistance value after the application of the resetting current is approximately 10 KΩ. An adequate resistance ratio is attainable after approximately 10⁷ to 10⁸ rewriting cycles. Furthermore, the reason the resistance ratio is achieved through repeating the rewriting of the recording layer 15 is that, as explained above, repeated rewriting cycles cause the Ti of the adhesion layer 14 to gradually diffuse along the grain boundary of the particles of the GST or other material that constitutes the recording layer 15. When approximately 10⁶ to 10⁷ rewritings have been performed, the effect of the Ti is eliminated.

As explained above, in the method of manufacturing a non-volatile memory element according to the present embodiment, when an adhesion layer 14 of Ti or the like is provided to the interface between the interlayer insulating film 11 and the recording layer 15, the Ti of the adhesion layer 14 can be made to diffuse into the recording layer 15 using a relatively weak current supplied by the transistors without using nitrogen-added GST as the recording layer. This causes the heat generation efficiency to be already high when the device is used. Therefore, a set state (crystalline state) can be readily converted to a reset state (amorphous state).

Thus, nitrogen does not need to be added to the recording layer 15 in the present embodiment, for which reason the characteristics of the chalcogenide material that constitutes the recording layer 15 cannot be affected by the nitrogen in any way. However, it is not essential that nitrogen be excluded from the recording layer 15 in the present embodiment, and a certain amount of nitrogen may be added. The number of rewriting cycles necessary for initialization may accordingly be reduced. Furthermore, instead of alternating repetitions of supplying the resetting current and supplying the setting current as the initialization step, a resetting current alone may be intermittently supplied.

According to the present embodiment, the adhesion layer 14 remains substantially intact until just before the initialization step is executed. Therefore, the recording layer 15 can be reliably prevented from detaching during the manufacturing step. Additionally, even after the initialization step has concluded, diffusion of the adhesion layer 14 is limited to the vicinity of the lower electrodes 12 used as heaters. Since the adhesion layer 14 remains intact in other regions, a decrease in adhesion due to initialization substantially does not occur.

In the second embodiment described above, the adhesion layer 14 only above the lower electrode 12 is vanished by performing the initializing process of non-volatile memory element having the recording layer without added nitrogen. However, the adhesion layer 14 above the lower electrode 12 may be removed by photolithography and dry-etching after laminating the adhesion layer 14.

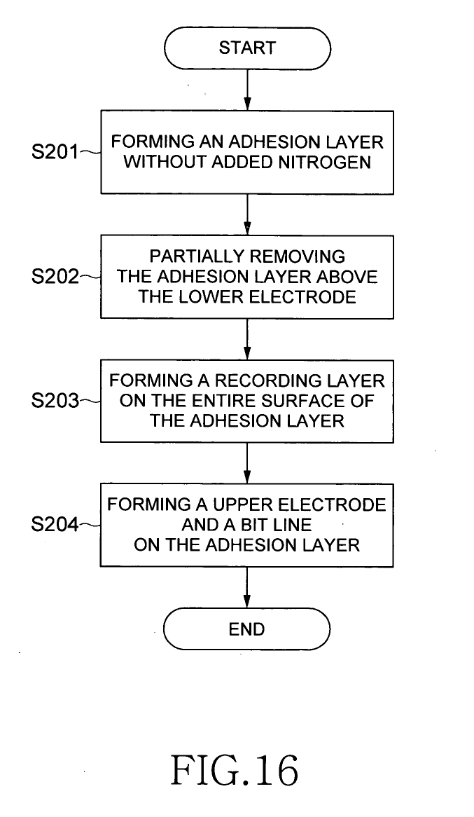

FIG. 16 is a flowchart showing a method of manufacturing a non-volatile memory element according to a third preferred embodiment of the present invention.

As shown in FIG. 16, in the manufacture of a non-volatile memory element according to the present embodiment, first, an adhesion layer 14 without added nitrogen is formed (S201). The adhesion layer 14 is formed on an interlayer insulating film 11 so that an electrical connection is established with a lower electrode 12. Next, the adhesion layer 15 above the lower electrodes 12 is partially removed by photolithography and dry-etching (S202). Furthermore, recording layer 15 containing a phase change material is formed on the entire surface of the adhesion layer 14 including the exposure surface of the lower electrode 12 (S203), after which the upper electrode 16 and the bit line Bj are formed on the recording layer 15 (S204). Accordingly, the non-volatile memory element as shown in FIG. 14 can be manufactured. According to the present embodiment, it is possible to remove the adhesion layer 14 on the lower electrode 12 without initializing process.

Preferred embodiments of the present invention have been explained above, but the present invention is not limited thereto. A variety of modifications are possible within the scope of the main points of the present invention, and it shall be apparent that these modifications are also included within the scope of the present invention.

For example, the structure of the transistors Tr shown in FIG. 1 and the like is merely an example, and a variety of structures may be adopted for the transistors that drive the non-volatile memory element according to the present invention. Additionally, the upper electrodes 16 of a pair of non-volatile memory elements 10 are connected to a common bit line Bj, and are accordingly configured as a continuous electrode. However, the upper electrodes 16 may be provided separately to each non-volatile memory element 10. Further, the upper electrodes 16 may themselves be used as bit lines Bj instead of the upper electrodes 16 and the bit lines Bj being provided separately.

What is claimed is:

1. A method of manufacturing a non-volatile memory element, comprising:
a first step for forming an adhesion layer on an interlayer insulating film so that an electrical connection is established with a lower electrode;
a second step for forming a recording layer containing a phase change material on the adhesion layer;
a third step for forming an upper electrode that is electrically connected to the recording layer; and
a fourth step for diffusing in the recording layer some of the adhesion layer positioned between at least the lower electrode and the recording layer.

2. The method of manufacturing a non-volatile memory element as claimed in claim 1, wherein the second step includes a step wherein the phase change material is formed into a film in an inert gas atmosphere with which an additive has been mixed.

3. The method of manufacturing a non-volatile memory element as claimed in claim 2, wherein the additive contains nitrogen.

4. The method of manufacturing a non-volatile memory element as claimed in claim 3, wherein the amount of nitrogen added is 1 to 10% in terms of the ratio of flow relative to that of the inert gas.

5. The method of manufacturing a non-volatile memory element as claimed in claim 1, wherein the interlayer insulating film includes silicon oxide.

6. The method of manufacturing a non-volatile memory element as claimed in claim 1, wherein the adhesion layer contains titanium (Ti).

7. The method of manufacturing a non-volatile memory element as claimed in claim 1, wherein the film thickness of the adhesion layer is 1 to 4 nm.

8. The method of manufacturing a non-volatile memory element as claimed in claim 1, wherein the phase change material contains a chalcogenide material.

9. The method of manufacturing a non-volatile memory element as claimed in claim 8, wherein the chalcogenide material is Ge₂Sb₂Te₅ (GST).

10. The method of manufacturing a non-volatile memory element as claimed in claim 1, wherein the fourth step includes a step for performing a heat treatment at a prescribed temperature.

11. The method of manufacturing a non-volatile memory element as claimed in claim 10, wherein the prescribed temperature is preferably 350° C. or more.

12. The method of manufacturing a non-volatile memory element as claimed in claim 1, the fourth step is an initialization step for repeating the rewriting of the recording layer.

13. The method of manufacturing a non-volatile memory element as claimed in claim 12, the number of repeated rewritings is 10⁵ or more.

14. A method of manufacturing a non-volatile memory element, comprising:
a first step for forming an adhesion layer on an interlayer insulating film so that an electrical connection is established with a lower electrode;
a second step for removing a part of the adhesion layer on a lower electrode;
a third step for forming a recording layer containing a phase change material on the adhesion layer including an exposure surface of the lower electrode; and
a forth step for forming an upper electrode that is electrically connected to the recording layer.
